(19) United States
(12) Patent Application Publication
(10) Pub. No.: US 2010/0176831 A1
(43) Pub. Date: Jul. 15, 2010

(54) Probe Test Card with Flexible Interconnect Structure

(76) Inventors: William M. Palcisko, Gilbert, AZ (US); Gerald W. Back, Gilbert, AZ (US); Bahadir Tunaboylu, Chandler, AZ (US)

Correspondence Address: HICKMAN PALERMO TRUONG & BECKER, LLP, 2055 GATEWAY PLACE, SUITE 550, SAN JOSE, CA, 95110, US

(21) Appl. No.: 12/353,879

(22) Filed: Jan. 14, 2009

(51) Int. Cl. G01R 31/02

(52) U.S. Cl. 324/757; 324/754

(57) ABSTRACT

A probe test card assembly for testing of a device under test includes a printed circuit board (PCB), a space transformer, a probe head structure and a flexible interconnect structure. The space transformer has a first plurality of electrical contacts disposed thereon for providing electrical connections with a plurality of contacts disposed on the PCB and a second plurality of electrical contacts disposed thereon for making contact with a plurality of test probes. Each test probe from the plurality of test probes has a first end for making electrical contact with a device under test and a second end for making electrical contact with one of the electrical contacts from the second plurality of electrical contacts on the space transformer. The flexible interconnect structure provides electrical connections between the first plurality of electrical contacts on the space transformer and the plurality of electrical contacts on the PCB.

### FIELD OF THE INVENTION

This invention relates generally to integrated circuit testing using probe cards.

### BACKGROUND

The approaches described in this section are approaches that could be pursued, but not necessarily approaches that have been previously conceived or pursued. Therefore, unless otherwise indicated, the approaches described in this section may not be prior art to the claims in this application and are not admitted to be prior art by inclusion in this section.

In semiconductor integrated circuit manufacturing, it is conventional to test integrated circuits (“IC's”) during manufacturing and prior to shipment to ensure proper operation. Wafer testing is a well-known testing technique commonly used in production testing of wafer-mounted semiconductor IC's, wherein a temporary electrical connection is established between automatic test equipment (ATE) and each IC formed on the wafer to demonstrate proper performance of the IC's. Components that may be used in wafer testing include an ATE test board, which is a multilayer printed circuit board that is connected to the ATE, and that transfers the test signals between the ATE and a probe card assembly. The probe test card assembly (or probe card) includes a printed circuit board that generally contains several hundred probe needles (or “probes”) positioned to establish electrical contact with a series of connection terminals (or “die contacts”) on the IC wafer. Conventional probe card assemblies include a printed circuit board, a substrate or probe head having a plurality of flexible test probes attached thereto, and an interposer that electrically connects the probes to the printed circuit board. The interposer conventionally includes telescopic “pogo pins” or solder bumps that provide electrical connections between conductive pads on the printed circuit board and the interposer and between the interposer and conductive pads on the substrate. The test probes are conventionally mounted to electrically conductive, typically metallic, bonding pads on the substrate using solder attach, wire bonding or wedge bonding techniques

The pogo pin or solder bump connections used with conventional probe card assemblies have some significant limitations. For example, pogo pins use spring components that exert a high aggregate amount of force against the substrate when used in large numbers. The spring components used in pogo pins can also stick or wear out over time, resulting in a “floating contact.” Pogo pins are also generally very labor intensive to install, especially in high density applications, and do not have high planarity. They have high deflection capability but their coplanarity is poor. The high force exerted by pogo pins can deflect, misalign or even crack a substrate. Thus, pogo pins are not a scalable solution for higher density applications. Solder bumps do not have the same spring component-related problems as pogo pins, but solder bumps sometimes do not provide reliable electrical contact, resulting in floating contacts, i.e., an open circuit. Also, solder bumps are not readily repairable, since they are normally created using solder flow techniques that cannot be used to repair an individual solder bump. Solder reflow technology works well only for smaller reflow areas—scalability to 10 and 12 inches would be a problem.

Based on the foregoing, there is a need for a probe card assembly that does not suffer from limitations of conventional probe card assemblies.

### BRIEF DESCRIPTION OF THE DRAWINGS

In the figures of the accompanying drawings like reference numerals refer to similar elements.

FIG. 1A depicts a probe card assembly for testing a device under test (DUT).

FIG. 1B depicts another example implementation of probe card assembly for testing a device under test (DUT).

FIG. 1C depicts a flexible interconnect structure connected to a printed circuit board (PCB) via a solder connection 126.

FIG. 1D depicts a wire bond connection connected to a contact point on a PCB and a contact point on a space transformer and provides an electrical connection between contact points.

FIG. 2A depicts an example probe test card assembly that includes a PCB, a space transformer, a probe head structure and a flexible interconnection structure.

FIG. 2B depicts an example portion of a guide plate that includes apertures.

FIG. 2C depicts several examples of pre-buckled tests probes.

### DETAILED DESCRIPTION

In the following description, for the purposes of explanation, numerous specific details are set forth in order to provide a thorough understanding of the present invention. It will be apparent, however, to one skilled in the art that the present invention may be practiced without these specific details. In other instances, well-known structures and devices are shown in block diagram form in order to avoid unnecessarily obscuring the present invention. Various aspects of the invention are described hereinafter in the following sections:

I. OVERVIEW

II. PROBE CARD ASSEMBLY WITH FLEXIBLE INTERCONNECT STRUCTURE

III. ATTACHMENT OF FLEXIBLE INTERCONNECT STRUCTURE

IV. PROBE HEAD STRUCTURES

V. TEST PROBES

### I. Overview

A probe test card assembly for testing of a device under test includes a printed circuit board, a space transformer, a probe head structure and a flexible interconnect structure. The printed circuit board has a plurality of electrical contacts disposed thereon. The space transformer has a first plurality of electrical contacts disposed thereon for providing electrical connections with the plurality of contacts disposed on the printed circuit board. The space transformer also includes a second plurality of electrical contacts disposed thereon for making contact with a plurality of test probes. The probe head structure supports the plurality of test probes. Each test probe from the plurality of test probes has a first end for making electrical contact with a device under test and a second end for making electrical contact with one of the electrical contacts from the second plurality of electrical contacts on the space transformer. The flexible interconnect structure provides electrical connections between the first plurality of electrical contacts on the space transformer and the plurality of electrical contacts on the printed circuit board. The probe head structure may include first and second guide plates with apertures in which the plurality of test probes is disposed. The first and second guide plates constrain and align the plurality of test probes with test points on the device under test. The plurality of test probes may be pre-buckled to cause the plurality of test probes to deflect and/or bend in a specified direction.

II. Probe Card Assembly with Flexible Interconnect Structure

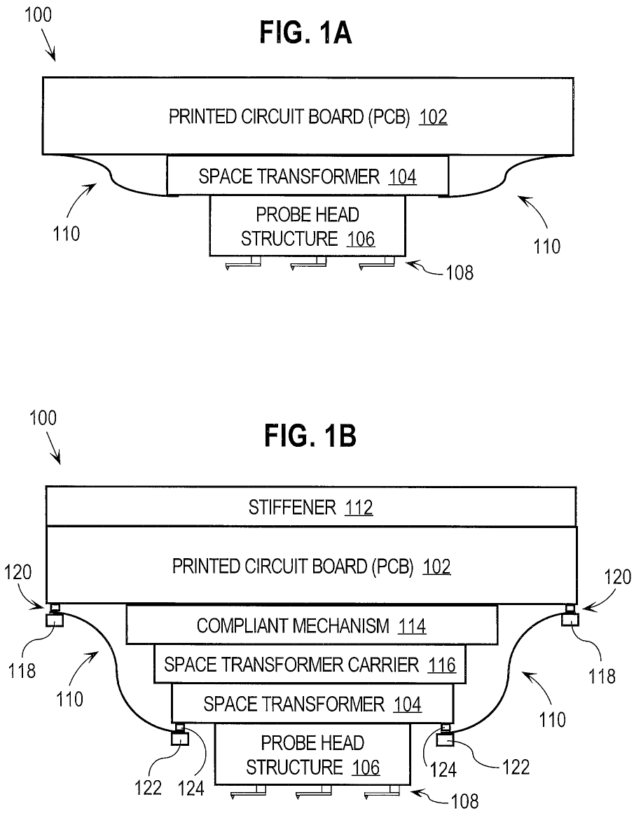

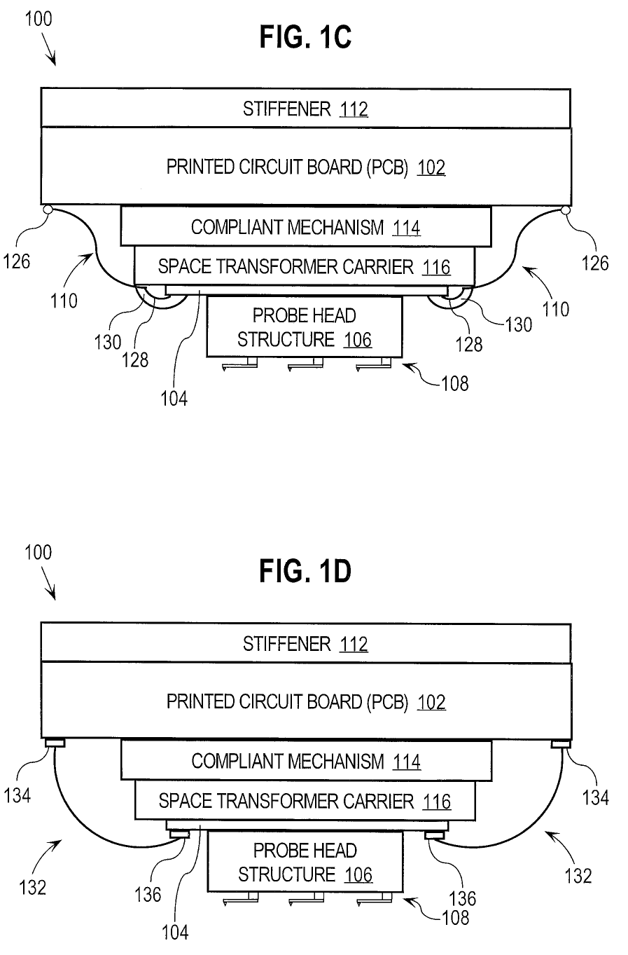

FIG. 1A depicts a probe card assembly 100 for testing a device under test (DUT) 102. The probe card assembly 100 includes a printed circuit board (PCB) 102, a space transformer 104 and a probe head structure 106. The PCB 102 provides electrical connections to test equipment and space transformer 104 provide electrical connections between the PCB 102 and the probe head structure 106, which is typically smaller than the space transformer 104. Space transformer 104 may be made as a single layer of material or from multiple layers. For example, space transformer 104 may be a multi-layer ceramic (MLC). As another example, space transformer 104 may be a Multi-Layer Silicon (MLS) space transformer made using silicon wafer fabrication techniques. An MLS space transformer may provide finer contact pitch, compared to an MLC space transformer. The probe head structure 106 supports a plurality of test probes 108 that make contact with a device under test. In FIG. 1A, the plurality of test probes 108 are depicted in FIG. 1A as cantilever test probes, but any type of test probe may be used, including vertical test probes. Probe card assembly 100 also includes a flexible interconnect structure 110 that provides electrical connections between PCB 102 and space transformer 104. Flexible interconnect structure 110 may be implemented using a variety of mechanisms. One example implementation of flexible interconnect structure is one or more flexible circuits. Probe card assembly 100 may include numerous other components and elements, as described in more detail hereinafter.

FIG. 1B depicts another example implementation of probe card assembly 100 for testing a device under test (DUT) 102. In this example, probe card assembly 100 also includes a stiffener 112, a compliant mechanism 114 and a space transformer carrier 116. Stiffener 112 provides structural support for PCB 102 in situations where additional structural support is desirable. For example, it is helpful to include stiffener 112 when PCB 102 is made from a flexible material. Compliant mechanism 114 and space transformer carrier 116 support space transformer 104 with respect to PCB 102. Stiffener 112, compliant mechanism 114 and space transformer carrier 116 are examples of other types of structures that may be included in probe card assembly 100 and probe card assembly 100 is not limited to the particular structures and elements depicted in the figures and described herein.

### III. Attachment of Flexible Interconnect Structure

As previously described herein, flexible interconnect structure 110 may be implemented using one or more flexible circuits. For example, a single flexible circuit may be used to connect a plurality of electrical contacts on PCB 102 to a plurality of electrical contacts on space transformer 104. Thus, in a situation where PCB 102 and space transformer 104 are rectangular in shape, four flexible circuits may be used. Alternatively, more than one flexible circuit may also be used on each side of PCB 102 and space transformer 104. For example, PCB 102 or space transformer 104 may have multiple rows or “banks” of electrical contacts and a separate flexible circuit may be used for each row or bank of electrical contacts. The flexible circuits may be arranged side by side or may overlap, depending upon the requirements of a particular implementation. Flexible interconnect structure 110 may be connected to PCB 102 and space transformer 104 using a variety of techniques and mechanisms. For example, as depicted in FIG. 1A, a clamping mechanism 118 may be used to hold flexible interconnect structure 110 in contact with contacts 120 on PCB 102. Similarly, a clamping mechanism 122 may be used to hold flexible interconnect structure 110 in contact with contacts 124 on space transformer 104. Examples of contacts 122, 124 include, without limitation, flat contacts and raised contacts, such as solder balls. Different types of flexible circuits may be used, including flexible circuits having contacts on one or multiple sides. One example of a flexible circuit is a flexible substrate on which copper traces are formed. The characteristics of the flexible circuit used, e.g., thickness, width, contact pitch, etc., may vary, depending upon the requirements of a particular implementation.

As another example, as depicted in FIG. 1C, flexible interconnect structure 110 may be connected to PCB 102 via a solder connection 126. For example, contacts on one end of the flexible interconnect structure 110 may be soldered to electrical contacts on PCB 102. The other end of flexible interconnect structure 110 is connected, e.g., mechanically pressed or bonded, to space transformer carrier 116. A wire bond 128 provides an electrical connection between flexible interconnect structure 110 and an electrical connection, for example a contact, on space transformer 104. For example, the wire bond 128 may be soldered to a contact on the flexible interconnect structure 110. A protective material 130, for example an epoxy material or potting material, may be applied over wire bond 128 to provide strain relief and to protect wire bond 128.

Although FIG. 1C depicts flexible interconnect structure 110 being attached to space transformer carrier 116, flexible interconnect structure 110 may be attached directly to space transformer 104, with wire bond 128 used to provide an electrical connection between the flexible interconnect structure 110 and an electrical contact on space transformer 104. For example, the flexible interconnect structure 110 may be attached to the periphery of space transformer 104, with wire bond 128 providing an electrical connection to an electrical contact or pad located closer to the center of space transformer 104. The wire bonding technique depicted in FIG. 1C may also be used to connect the flexible interconnect structure to PCB 102. Similarly, the solder connection technique depicted in FIG. 1C may also be used to connect the flexible interconnect structure 110 to space transformer 104.

As yet another example, as depicted in FIG. 1D, a wire bond connection 132 is connected to a contact point 134, such as a pad, on PCB 102 and a contact point 136 on space transformer 104, and provides an electrical connection between contact points 134, 136. Flexible interconnect structure 110 may include electrical contacts on one or both sides for making contact with PCB 102 and/or space transformer 104. Furthermore, PCB 102 and space transformer 104 may include features, such as pads, contacts or bumps, e.g., wire bond bumps, to enhance the contact between flexible interconnection structure 110 and PCB 102 or space transformer 104.

### IV. Probe Head Structures

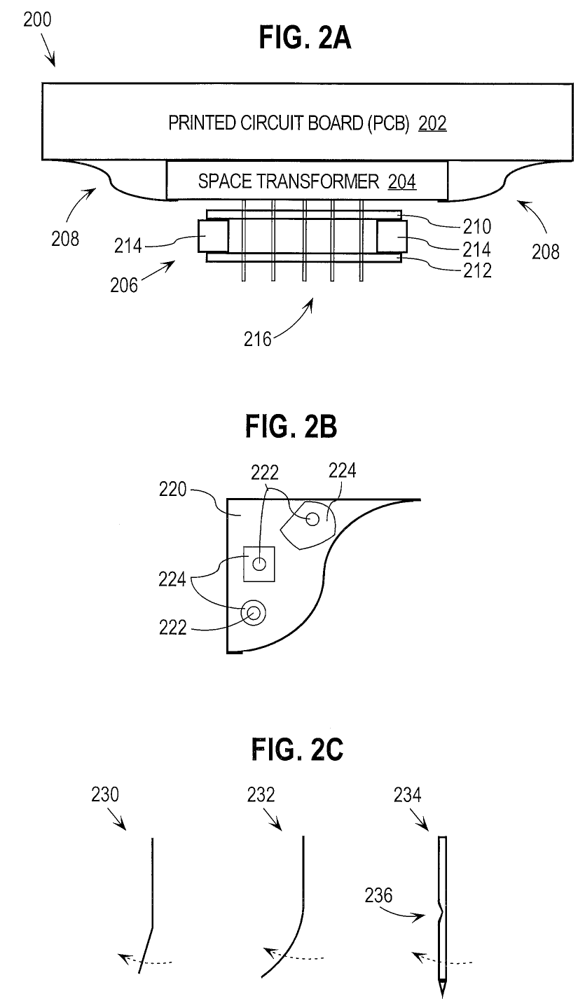

A wide variety of probe head structures may be used, depending upon a particular implementation. FIG. 2A depicts an example probe test card assembly 200 that includes a PCB 202, a space transformer 204, a probe head structure 206 and a flexible interconnection structure 210. In this example, probe head structure 206 includes a first guide plate 210 and a second guide plate 212 positioned via spacers 214. A plurality of test probes 216 extend through apertures in first guide plate 210 and second guide plate 212 and make contact with space transformer 204. The plurality of test probes 216 may make contact with pads or stud bumps on space transformer 204. The first guide plate 210 and the second guide plate 212 define and constrain the position of the test probes 216 to match a pattern of desired test points on a device under test. Spacers 214 provide a desired spacing between the first guide plate 210 and the second guide plate 212 and may also be used to attach the probe head structure 206 to the probe card assembly 200. Other structures, e.g., a fastener structure or components, may be used to hold probe head structure 206 in position with respect to space transformer 204 that are not depicted in FIG. 2A for purposes of explanation.

First guide plate 210, second guide plate 212 and spacers 214 may have a variety of shapes and dimensions, depending upon a particular implementation. For example, first guide plate 210, second guide plate 212 and spacers 214 may be rectangular or circular in shape, or may have irregular shapes. First guide plate 210, second guide plate 212 and spacers 214 may be made from a variety of materials. Example guide plate materials include, without limitation, plastic, silicon, silicon nitride and quartz. Example processes for making guide plates from silicon include, without limitation, Micro-Electro-Mechanical Systems (MEMS) and Deep Reactive Ion Etching (DRIE) micromachining processes. One benefit provided by the MEMS and DRIE processes is that they allow rectangular apertures or slots to be formed in the guide plates, which are more compatible with rectangular-shaped test probes, e.g., when the test probes are made using semiconductor fabrication techniques. Rectangular apertures or slots also provide further control over the deflection and bending of test probes, as described in more detail hereinafter. For silicon nitride, a laser fabrication process may be used. Other materials may be used, depending upon the requirements of a particular implementation. According to one embodiment of the invention, first guide plate 210 and/or second guide plate 212 are made from a rigid material to provide adequate alignment and thermal stability of the test probes, to ensure proper contact with a device under test. As described in more detail hereinafter, one or more portions or the entirety of first guide plate 210 and second guide plate 212 may be coated, for example, with a non-conductive material. This prevents shorts between test probes if the guide plate material is not sufficiently insulating. Example materials for spacers 214 include, without limitation, metals, such as steel, or other rigid materials that have good flatness and provide stability for first guide plate 210 and second guide plate 212.

FIG. 2B depicts an example portion of a guide plate 220 that includes apertures 222. In this example, apertures 224 are coated with a material 224. Material 224 may be a non-conductive material to prevent electrical shorts between test probes in situations where guide plate 220 is made of a conductive material. Example materials include, without limitation, insulating coating materials such as silicon dioxide (SiO₂), rubber and other non-conductive materials. As depicted in FIG. 2B, the material 224 may be applied in and around apertures 222 and may have different shapes and cover different portions of guide plate 220, depending upon the type of material 224 used and the manner in which the material 224 is applied. Guide plate 220 may also be entirely coated with a non-conductive material.

### V. Test Probes

Test probes 216 may be fabricated using a variety of techniques, depending upon a particular implementation. For example, test probes 216 may be stamped, electro-formed or fabricated using semiconductor fabrication techniques. Test probes 216 may be any type of test probe, such as cantilever test probes or vertical test probes. Test probes 216 may be made from a wide variety of materials, for example, aluminum or other metals or alloys. Test probes 216 may also have different shapes, depending upon a particular implementation. For example, test probes 116 may be round or rectangular and may be straight, bent or curved. Test probes 116 made from wires are typically round, while test probes 116 made using semiconductor fabrication techniques are typically rectangular. Test probes 116 may be partially or fully coated to change their physical or conductive characteristics. Test probes 116 may also be fabricated with features, e.g., notches, ridges, lips, protrusions, etc., that automatically position the test probes 116 within the first guide plate 210 and second guide plate 212.

According to one embodiment of the invention, test probes 216 are pre-buckled so that they deflect in generally a specified direction when test probes 216 make contact with a device under test. This reduces the likelihood that test probes 216 will deflect and/or bend in different directions and contact each other causing shorts when moved into contact with a device under test. It also increases the predictability of positioning of probe tips on a device under test.

A wide variety of techniques may be used to pre-buckle test probes. FIG. 2C depicts several examples of pre-buckled tests probes. Test probe 230 includes a bend that causes it to deflect and/or bend in the indicated direction when contact is made with a device under test. Similarly, test probe 232 is curved in a manner that causes it to deflect and/or bend in the indicated direction when contact is made with a device under test. Test probe 234 includes a feature 236, in the form of a notch, that causes test probe 234 to deflect and/or bend in the indicated direction when contact is made with a device under test. These are just a few examples of pre-buckling a test probe and many of techniques may be used. For example, other techniques may be used to weaken or pre-stress a test probe so that it will deflect and/or bend in a specified direction. As yet another example, test probes may be coated with a material or formed from various materials that cause the test probes to deflect and/or bend in a specified direction when contact is made with a device under test. In addition to the foregoing, the apertures in one or both the first guide plate 210 and the second guide plate 212 may be formed to assist in causing test probes to deflect and/or bend in a specified direction when they make contact with a device under test. For example, the test probes may include a rectangular-shaped portion that extends through and is positioned in rectangular-shaped apertures in one or both the first guide plate 210 and the second guide plate 212. The rectangular-shaped, e.g., slotted, apertures constrain the test probes and cause them to deflect and/or bend in a specified direction, e.g, in the direction of the slot, without rotating or twisting. This prevents the test probes from touching each other and causing shorts when the test probes make contact with a device under test.

The probe test card assembly with a flexible interconnect structure as described herein has several benefits over conventional probe test cards. In particular, the flexible interconnect structure provides a compliant connection between the printed circuit board and the space transformer without applying a large force load to the space transformer. This allows the PCB and space transformer to be placed at different heights with respect to each other. The flexible interconnect structure also provides control over signal impedance. The use of a clamping mechanism to attach the flexible interconnect structure to the printed circuit board and/or the space transformer reduces the uncontrolled impedance length of the contact and allows removal of the space transformer from the printed circuit board. Use of wire bond or solder connections between the flexible interconnect structure and the space transformer eliminates the need for a clamping mechanism, which reduces the space and alignment tolerance requirements.

In the foregoing specification, embodiments of the invention have been described with reference to numerous specific details that may vary from implementation to implementation. Thus, the sole and exclusive indicator of what is, and is intended by the applicants to be the invention is the set of claims that issue from this application, in the specific form in which such claims issue, including any subsequent correction. Hence, no limitation, element, property, feature, advantage or attribute that is not expressly recited in a claim should limit the scope of such claim in any way. The specification and drawings are, accordingly, to be regarded in an illustrative rather than a restrictive sense.

What is claimed is:

1. A probe test card assembly comprising:
a printed circuit board having a plurality of electrical contacts disposed thereon;
a space transformer having a first plurality of electrical contacts disposed thereon for providing electrical connections with the plurality of electrical contacts disposed on the printed circuit board and a second plurality of electrical contacts for making contact with a plurality of test probes;
a probe head structure supporting the plurality of test probes, each test probe in the plurality of test probes having a first end for making electrical contact with a device under test and a second end for making electrical contact with one of the electrical contacts from the second plurality of electrical contacts on the space transformer; and
a flexible interconnect structure connected to the first plurality of electrical contacts on the space transformer and to the plurality of electrical contacts on the printed circuit board for providing electrical contact between the first plurality of electrical contacts on the space transformer and the plurality of electrical contacts on the printed circuit board.

2. The probe test card assembly recited in claim 1, further comprising one or more clamping mechanisms for attaching the flexible interconnect structure to one or more of the plurality of electrical contacts on the printed circuit board or the first plurality of electrical contacts on the space transformer.

3. The probe test card assembly recited in claim 1, further comprising one or more wire bond bumps disposed on the plurality of electrical contacts on the printed circuit board or the first plurality of electrical contacts on the space transformer.

4. The probe test card assembly recited in claim 1, further comprising one or more wire bond bumps disposed on the flexible interconnect structure to improve the contact between the flexible interconnect structure and the plurality of electrical contacts on the printed circuit board or the first plurality of electrical contacts on the space transformer.

5. The probe test card assembly recited in claim 1, wherein the flexible interconnect structure is solder bonded to the plurality of electrical contacts on the printed circuit board.

6. The probe test card assembly recited in claim 1, wherein:
the flexible interconnect structure is bonded to the printed circuit board, and
the probe test card assembly further comprises one or more wire bonds connected between the flexible interconnect structure and the plurality of electrical contacts on the printed circuit board.

7. The probe test card assembly recited in claim 1, wherein:
the flexible interconnect structure is bonded to the space transformer, and
the probe test card assembly further comprises one or more wire bonds connected between the flexible interconnect structure and the first plurality of electrical connections on the space transformer.

8. The probe test card assembly recited in claim 1, wherein:
the flexible interconnect structure is solder bonded to the plurality of electrical contacts on the printed circuit board,
the flexible interconnect structure is bonded to the space transformer, and
the probe test card assembly further comprises one or more wire bonds connected between the flexible interconnect structure and the first plurality of electrical connections on the space transformer.

9. The probe test card assembly recited in claim 1, wherein the space transformer is a multi-layer silicon space transformer.

10. The probe test card assembly recited in claim 1, wherein the flexible interconnect structure is one or more flexible circuits.

11. The probe test card assembly recited in claim 1, wherein the probe head structure includes:
a first guide plate having a plurality of apertures disposed therein, and
a second guide plate having a plurality of apertures disposed therein,
wherein the plurality of test probes extend through the plurality of apertures disposed in the first guide plate and the plurality of apertures disposed in the second guide plate.

12. The probe test card assembly recited in claim 6, wherein the plurality of apertures disposed in the first guide plate and the plurality of apertures disposed in the second guide plate are coated with a non-conductive material.

13. The probe test card assembly recited in claim 1, wherein the space transformer is a multi-layer silicon space transformer.

14. A probe test card assembly comprising:
a printed circuit board having a plurality of electrical contacts disposed thereon;
a space transformer having a first plurality of electrical contacts disposed thereon and that are electrically connected to the plurality of electrical contacts on the printed circuit board, the space transformer further having a second plurality of electrical contacts; and
a probe head structure supporting a plurality of test probes, each test probe in the plurality of test probes having a first end for making electrical contact with a device under test and a second end for making electrical contact with one of the electrical contacts from the second plurality of electrical contacts on the space transformer, wherein the probe head structure comprises:
a first guide plate having a plurality of apertures formed therein,
a second guide plate having a plurality of apertures formed therein, and
wherein the plurality of test probes are disposed through both the plurality of apertures in the first guide plate and the plurality of apertures in the second guide plate.

15. The probe test card assembly recited in claim 14, wherein one or more test probes from the plurality of test probes are pre-buckled so that they deflect in a specified direction when in contact with the device under test.

16. The probe test card assembly recited in claim 15, wherein the one or more test probes have a generally rectangular cross sectional shape.

17. The probe test card assembly recited in claim 16, wherein the plurality of apertures in the first guide plate and the plurality of apertures in the second guide plate are generally rectangular in shape to receive the one or more test probes having a generally rectangular cross sectional shape.

18. The probe test card assembly recited in claim 14, wherein:
the second guide plate is adjacent the first end of each of the plurality of test probes, and
the second guide plate is made of a rigid material.

19. The probe test card assembly recited in claim 14, wherein the plurality of apertures in the second guide plate is coated with a non-conductive material.

20. The probe test card assembly recited in claim 14, wherein:
the first guide plate is adjacent the second end of each of the plurality of test probes, and
the first guide plate is made of a plastic material.

21. The probe test card assembly recited in claim 14, further comprising a flexible interconnect structure that provides electrical connections between the first plurality of electrical contacts on the printed circuit board and the first plurality of electrical contacts on the space transformer.
